(19) United States
(12) Patent Application Publication
(10) Pub. No.: US 2014/0054076 A1
(43) Pub. Date: Feb. 27, 2014

(54) CONDUCTIVE COMPONENT AND PREPARATION METHOD THEREOF

(71) Applicants: Zhizheng Cheng, Shenzhen (CN); Rongjun Cai, Nanchang (CN)

(72) Inventors: Zhizheng Cheng, Shenzhen (CN); Rongjun Cai, Nanchang (CN)

(73) Assignee: SHENZHEN O-FILM TECH CO., LTD., Shenzhen, Guangdong (CN)

(21) Appl. No.: 14/000,157

(22) PCT Filed: Dec. 21, 2012
(86) PCT No.: PCT/CN2012/087198

§ 371 Date: Aug. 16, 2013

(30) Foreign Application Priority Data
Apr. 19, 2012 (CN) 201210116164.1
Apr. 19, 2012 (CN) 201210116181.5

(51) Int. Cl. H05K 1/02; H05K 3/14

(52) U.S. Cl. CPC H05K 1/0296; H05K 3/14; H05K 3/146
USPC 174/257; 174/250; 174/258; 427/79

(57) ABSTRACT

A conductive component is disclosed in the present invention, which includes an insulating layer and a metal mesh arranged on the insulating layer, the metal mesh defines a plurality of voids arranged in array, the aperture ratio K of the voids of the metal mesh and the optical transmittance T₁ of the conductive component and the optical transmittance T₂ of the insulating layer being described as formula: T₁=T₂*K. The metal mesh is arranged on the insulating layer in the conductive component, a patterned sensing layer on the insulating layer by the metal mesh treated by exposure and development as needed when in use, and then applied to touch screen, the use of indium tin oxide is avoided in the conductive component, thus the cost of the conductive component is low. A method of preparing the conductive component is also provided.

### FIELD OF THE INVENTION

The present invention relates to a conductive component and a preparation method thereof.

### BACKGROUND OF THE INVENTION

Recently, the capacitive touch screen is more and more favored by the market due to a lot of advantages, such as high transparency, multi-touch, long life and so on. Currently, the transparent conductive material (indium tin oxide, ITO) is coated on a glass substrate by vacuum evaporation deposition or magnetron sputtering to form a conductive component applied to the capacitive touch screen.

However, indium is a rare earth element, which has relatively small reserves in nature, and is expensive, thereby bringing high costs to the conductive component.

### SUMMARY OF THE INVENTION

One object of the present invention is to provide a low-cost conductive component and a preparation method thereof.

A conductive component includes an insulating layer and a metal mesh arranged on the insulating layer, the insulating layer having a first surface and a second surface opposite to the first surface, the metal mesh including two layers, one layer of the metal mesh is arranged on the first surface of the insulating layer, the other layer of the metal meshes is arranged on the second surface of the insulating layer, the metal meshes defining a plurality of voids arranged in array, a relationship of the aperture ratio K of the voids of the metal mesh, the optical transmittance T₁ of the conductive component, and the optical transmittance T₂ of the insulating layer being described as formula: T₁=T₂*K.

In one embodiment, the voids are square or diamond, the metal mesh includes a plurality of parallel first metal lines and a plurality of parallel second metal lines, the first metal lines and the second metal lines are intersected with each other to form the voids.

In one embodiment, at least one of the first metal lines and the second metal lines is solid line or grid line.

In one embodiment, the widths of the first metal lines and the second metal lines are greater than or equal to 45 nm and less than or equal to 40000 nm.

In one embodiment, the widths of the first metal lines and the second metal lines are greater than or equal to 45 nm and less than or equal to 5000 nm.

In one embodiment, the voids of the metal meshes are regular hexagons in a honeycomb arrangement.

In one embodiment, the voids of the metal mesh are triangular, the metal mesh includes a plurality of paralleled first metal lines, a plurality of paralleled second metal lines and a plurality of paralleled third metal lines, the first metal lines and the second metal lines are leant to and intersected with each other to form a plurality of diamond voids arranged in array, the third metal lines pass through two opposite ends of the corresponding diamond voids to divide the diamond voids into triangular voids.

In one embodiment, at least one of the first metal lines, the second metal lines and the third metal lines is solid line or grid line.

In one embodiment, the widths of the first metal lines, the second metal lines and the third metal lines are greater than or equal to 45 nm and less than or equal to 5000 nm.

In one embodiment, the widths of the first metal lines, the second metal lines and the third metal lines are greater than or equal to 45 nm and less than or equal to 5000 nm.

In one embodiment, the metal meshes are provided with an anti-oxidation layer on a surface thereof, the anti-oxidation layer is made of a material selected from the group consisting of gold, platinum, nickel, and nickel-gold alloy.

In one embodiment, an orthographic projection of the metal mesh arranged on the first surface of the insulating layer to the second surface overlaps the metal mesh arranged on the second surface of the insulating layer.

In one embodiment, the insulating layer is a glass substrate or a plastic film.

In one embodiment, the glass substrate is made of a material selected from the group consisting of inorganic silicate glass and polymethyl methacrylate.

In one embodiment, the plastic film is made of a material selected from the group consisting of polyethylene terephthalate and polycarbonate.

In one embodiment, the insulating layer is provided with a functional layer having functions of anti-dazzle, hardening, antireflection and atomization on a surface thereof, the metal meshes are formed on the surfaces of the functional layer.

In one embodiment, the functional layer having the function of antireflection is selected from the group consisting of titanium dioxide coating, magnesium fluoride coating and calcium fluoride coating.

In one embodiment, the thicknesses of the metal meshes are greater than or equal to 45 nm and less than or equal to 40000 nm.

A method of preparing a conductive component, including the following steps:

forming two metal layers on a first surface and a second surface opposite to the first surface of an insulating layer, respectively; and

processing the metal layers to form a metal mesh with two layers respectively arranged on the first surface and the second surface of the insulating layer by exposure and development, and the metal mesh defining a plurality of voids arranged in array, a relationship of the aperture ratio K of the voids of the metal mesh, the optical transmittance T₁ of the conductive component, and the optical transmittance T₂ of the insulating layer being described as the formula: T₁=T₂*K.

In one embodiment, the voids are square or diamond, the metal mesh includes a plurality of paralleled first metal lines and a plurality of paralleled second metal lines, the first metal lines and the second metal lines are intersected with each other to form the voids.

In one embodiment, at least one of the first metal lines and the second metal lines is solid line or grid line.

In one embodiment, the widths of the first metal lines and the second metal lines are greater than or equal to 45 nm and less than or equal to 40000 nm.

In one embodiment, the widths of the first metal lines and the second metal lines are greater than or equal to 45 nm and less than or equal to 5000 nm.

In one embodiment, the voids of the metal meshes are regular hexagon in a honeycomb arrangement.

In one embodiment, the voids of the metal meshes are triangular, the metal mesh includes a plurality of paralleled first metal lines, a plurality of paralleled second metal lines and a plurality of paralleled third metal lines, the first metal lines and the second metal lines are leant to and intersected to form a plurality of diamond voids arranged in array, the third metal lines pass through the two opposite ends of the corresponding diamond void to divide the diamond voids into triangular voids.

In one embodiment, at least one of the first metal lines, the second metal lines and the third metal lines is solid line or grid line.

In one embodiment, the widths of the first metal lines, the second metal lines and the third metal lines are greater than or equal to 45 nm and less than or equal to 40000 nm.

In one embodiment, the widths of the first metal lines, the second metal lines and the third metal lines are greater than or equal to 45 nm and less than or equal to 5000 nm.

In one embodiment, the metal meshes are provided with an anti-oxidation layer on a surface thereof, the anti-oxidation layer is made of a material selected from the group consisting of gold, platinum, nickel, and gold-nickel alloy.

In one embodiment, an orthographic projection of the metal mesh arranged on the first surface of the insulating layer to the second surface overlaps to the metal mesh arranged on the second surface of the insulating layer

In one embodiment, the insulating layer is a glass substrate or a plastic film.

In one embodiment, the glass substrate is made of a material selected from the group consisting of inorganic silicate glass and polymethyl methacrylate.

In one embodiment, the plastic film is made of a material selected from the group consisting of polyethylene terephthalate and polycarbonate.

In one embodiment, the insulating layer is provided with a functional layer having functions of anti-dazzle, hardening, antireflection and atomization on a surface thereof, the metal mesh is formed on the surface of the functional layer.

In one embodiment, the functional layer having the function of antireflection is selected from the group consisting of titanium dioxide coating, magnesium fluoride coating and calcium fluoride coating.

In one embodiment, the thicknesses of the metal meshes are greater than or equal to 45 nm and less than or equal to 40000 nm.

In the conductive component and a preparation method thereof, the metal meshes are arranged on surfaces of the insulating layer, the metal meshes may be formed patterned sensing layers on the insulating layer by exposure and development according to the need when in use, and then applied to touch screen, the use of indium tin oxide is avoided in the conductive component, thus the cost of the conductive component is low.

### BRIEF DESCRIPTION OF THE DRAWINGS

FIG. 1 is a schematic, cross-sectional view of an embodiment of a conductive component;

FIG. 2 is a schematic, view of a metal mesh of the conductive component shown in FIG. 1;

FIG. 3 is a schematic, view of a metal mesh of the conductive component in accordance with another embodiment ;

FIG. 4 is a schematic view of a metal mesh of the conductive component in accordance with another embodiment;

FIG. 5 is a schematic view of a metal mesh of the conductive component in accordance with another embodiment; and

FIG. 6 is a flowchart of an embodiment of a preparing method of the conductive component.

### DETAILED DESCRIPTION OF THE EMBODIMENTS

Reference will now be made to the drawings to describe, in detail, embodiments of the present conductive component and a preparation method thereof.

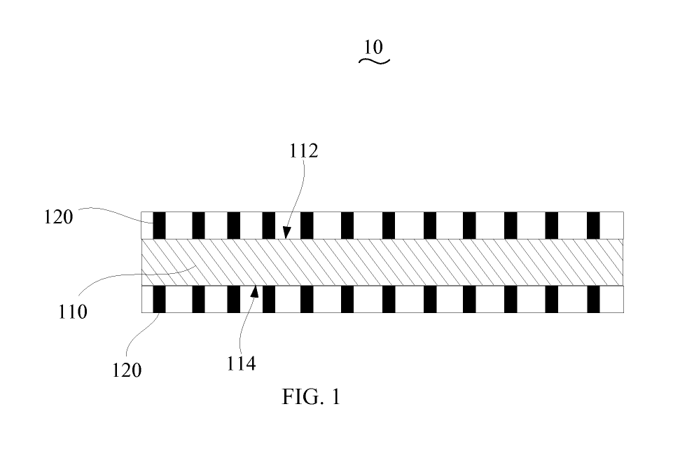

Referring to FIG. 1, an embodiment of a conductive component 10 includes an insulating layer 110 and a metal mesh 120.

The insulating layer 110 is substantially sheet-like. The insulating layer 110 has a first surface 112 and a second surface 114 opposite to the first surface 112.

The insulating layer 110 is a glass substrate or a plastic film. The glass substrate is made of a material of inorganic silicate glass or polymethyl methacrylate (PMMA). The plastic film is made of a material of polyethylene terephthalate (PET) or polycarbonate (PC). In a word, the insulating layer 110 is made of transparent insulating material.

Preferably, at least one of the first surface 112 and the second surface 114 of the insulating layer 110 is provided with a functional layer having functions of anti-dazzle, hardening, antireflection and atomization (not shown).

The functional layer having the functions of anti-dazzle or atomization is formed by coating a paint having the functions of anti-dazzle or atomization, the paint contains metal oxide particles; the functional layer having the function of hardening is formed by coating a polymer paint having the function of hardening; the functional layer having the function of antireflection is titanium dioxide coating, magnesium fluoride coating or calcium fluoride coating.

The metal mesh 120 includes two layers. One layer of the metal mesh 120 is arranged on the first surface 112 of the insulating layer 110, the other layer of the metal mesh 120 is arranged on the second surface 114 of the insulating layer 110. It should be noted that when the insulating layer 110 is provided with functional layers on the first surface 112 and the second surface 114, the metal mesh 120 is formed on the surfaces of the functional layers.

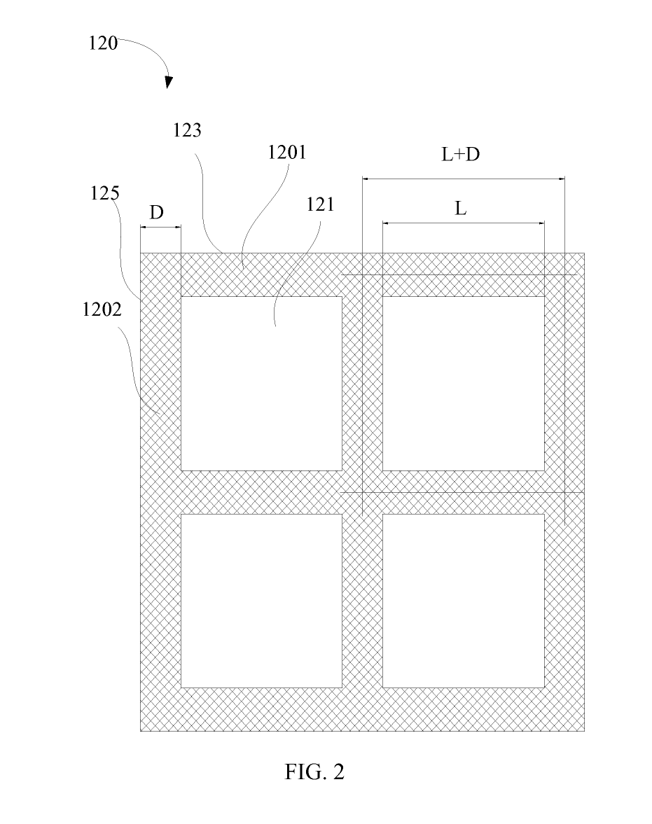

Referring to FIG. 2, the metal mesh 120 has a plurality of voids 121 arranged in array. In the illustrated embodiment, the shapes and sizes of the plurality of voids 121 are the same. Further, an orthographic projection of the metal mesh 120 arranged on the first surface 112 of the insulating layer 110 to the second surface 114 overlaps the metal mesh 120 arranged on the second surface 114.

In the illustrated embodiment, the voids 121 are square, the plurality of voids 121 are arranged in array. The metal mesh 120 includes a plurality of parallel first metal lines 123 and a plurality of parallel second metal lines 125. The first metal lines 123 and the second metal lines 125 are grid lines formed by a plurality of crisscrossing metal wires 1201. Each of the first metal lines 123 and the second metal lines 125 includes a plurality of meshes 1202, respectively. The first metal lines 123 and the second metal lines 125 are intersected to form the square voids 121 arranged in array, the area of the voids 121 is larger than that of the meshes 1202.

In the illustrated embodiment, the metal mesh 120 is made of copper, silver, molybdenum-aluminum-molybdenum alloy or copper-nickel alloy. In order to avoid the oxidation of the metal mesh 120, an anti-oxidation layer is formed on the surface of the metal mesh 120, the anti-oxidation layer is made of inert metal, such as gold, platinum, nickel, nickel-gold alloy and the like.

The widths (D) of the lines (i.e. the first metal lines 123 and the second metal lines 125) of the metal mesh 120 are greater than or equal to 45 nm and less than or equal to 40000 nm. It should be noted that the widths (D) of the lines of the metal mesh 120 have an impact to the resolution of the touch screen 10. When the widths (D) of the lines of the metal mesh 120 are too large, the lines will be seen, thus the resolution of the touch screen 10 may be influenced. Preferably, the widths (D) of the lines of the metal mesh 120 are greater than or equal to 45 nm and less than or equal to 5000 nm.

In order to ensure the sensitivity of the touch screen 10 to the signal, the relationship of the aperture ratio (K) of the metal mesh 120, the transmittance (T₁) of the conductive component 10, and the transmittance (T₂) of the insulating layer is described as the following formula: T₁=T₂*K. Thus the aperture ratio of metal mesh 120 satisfied with desired conditions may be calculated according to the designed transmittance of the conductive component 10.

Taking the following metal mesh 120 as an example, the voids 121 of the metal mesh 120 are square. The width of the lines of metal mesh 120 is D, the aperture widths of the voids 121 of the metal mesh 120 are L. The metal mesh 120 may be viewed as consisting of a plurality of unit cells with the length of side is D+L, the aperture ratio (K) of the metal mesh 120 equals to the area of the voids 121 divided by that of the unit cells. Specifically, in the illustrated embodiment, K=L²/(L+D)².

In the conductive component 10, the metal mesh 120 is arranged on the insulating layer 110. In use, a patterned sensing layer is formed on the insulating layer 110 by exposing and developing the metal mesh further as needed, and then applied to touch screen. The use of indium tin oxide is avoided in the conductive component 10, thus the cost of the conductive component 10 is low. Meanwhile, the transmittances of the metal mesh 120 is high. The square resistance of the conductive component 10 is as low as 1 Ω/sq. The transmittance of the conductive component 10 may be adjusted by modifying the aperture ratio of the metal mesh 120 and the transmittance of the insulating layer 110, it is much flexible.

It should be noted that the voids 121 of the metal mesh 120 are not limited to square shown in the FIG. 2, which may be polygonal, the first metal lines 123 and the second metal lines 125 are not limited to the grid lines formed of a plurality of crisscrossing metal wires 1201.

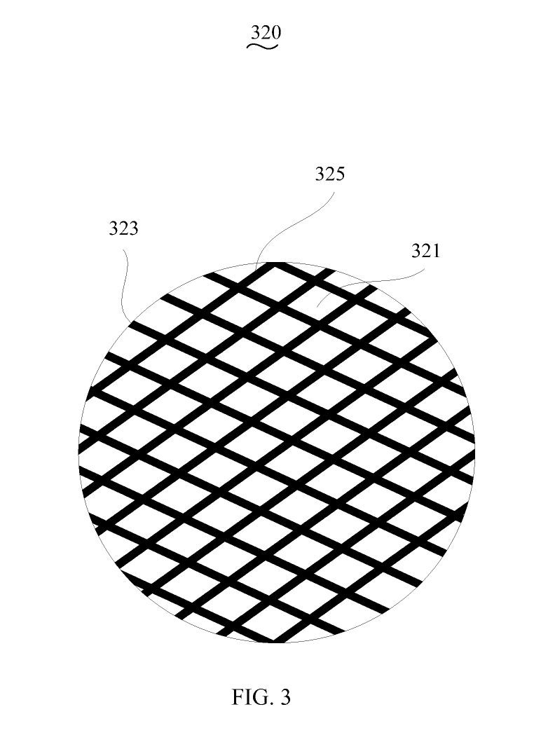

Referring to FIG. 3, a plurality of voids 321 of metal mesh 320 of another embodiment are diamond and arranged in array. The metal mesh 320 includes a plurality of parallel first metal lines 323 and a plurality of parallel second metal lines 325. The first metal lines 323 and the second metal lines 325 are intersected with and leant to each other to form a plurality of diamond voids 321 arranged in array, and the first metal lines 323 and the second metal lines 325 are solid lines.

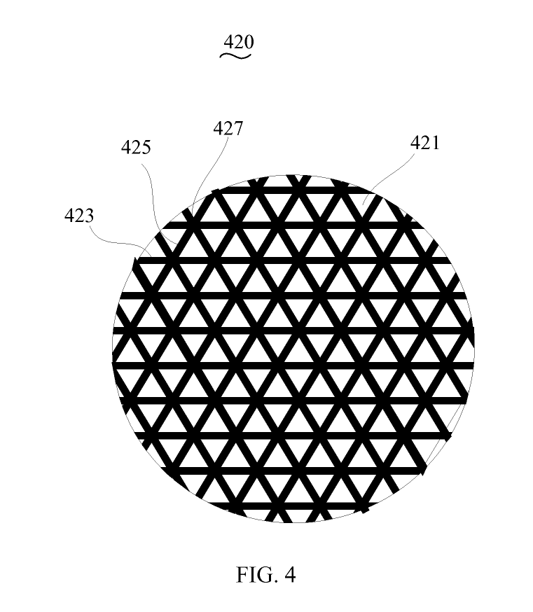

Referring to FIG. 4, voids 421 of the metal mesh 420 of another embodiment are triangular voids arranged in array. The metal mesh 420 includes a plurality of parallel first metal lines 423, a plurality of parallel second metal lines 425, and a plurality of parallel third metal lines 427. The first metal lines 423 and the second metal lines 425 are leant to and intersected with each other to form a plurality of diamond voids 421, and the third metal lines 427 are intersected with two opposite ends of the diamond voids to divide the diamond voids into triangular voids 421 arranged in array.

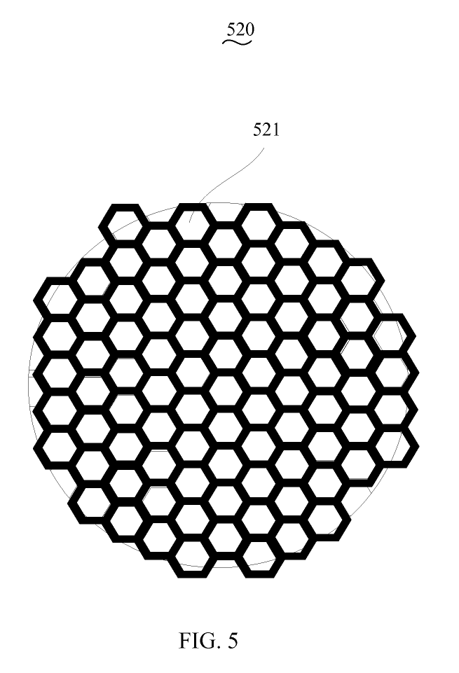

Referring to FIG. 5, voids 521 of metal mesh 520 of another embodiment are regular hexagons in honeycomb arrangement.

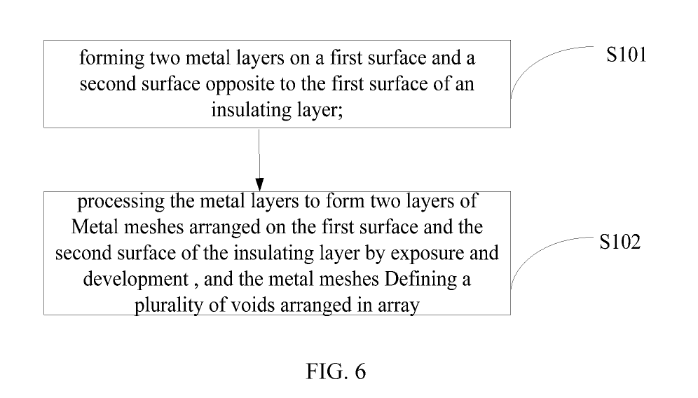

Referring to FIG. 1, FIG. 2 and FIG. 6, an embodiment of a preparing method of the conductive component includes the following steps:

S101, two metal layers are formed on the first surface 112 and the second surface 114 opposite to the first surface 112 of the insulating layer 110.

The insulating layer 110 is a glass substrate or a plastic film. The glass substrate is made of a material of inorganic silicate or polymethyl methacrylate (PMMA). The plastic film is made of a material of polyethylene terephthalate (PET) or polycarbonate (PC). In a word, the insulating layer 110 is made of transparent insulating material.

The thicknesses of the metal layers are greater than or equal to 45 nm and less than or equal to 40000 nm.

At least one of the first surface 112 and the second surface 114 of the insulating layer is provided with a functional layer having functions of anti-dazzle, hardening, antireflection and atomization (not shown).

The functional layer having the functions of anti-dazzle or atomization is formed by coating a coating having the functions of anti-dazzle or atomization, the coating contains metal oxide particles; the functional layer having the function of hardening is formed by coating a polymer coating having the function of hardening; the functional layer having the function of antireflection is titanium dioxide coating, magnesium fluoride coating or calcium fluoride coating.

The number of the metal layers is two, one of the layers of the metal layers is arranged on the first surface 112 of the insulating layer 110, and the other layer of the metal layers is arranged on the second surface 114 of the insulating layer 110. In the illustrated embodiment, the metal layers are formed by vacuum deposition, chemical vapor deposition or sol-gel method. The metal layers are made of a material of copper, silver, molybdenum-aluminum-molybdenum alloy or copper-nickel alloy. It should be noted that when the insulating layer 110 is provided with a functional layer on the first surface 112 and the second surface 114, the metal mesh 120 is formed on the surfaces of the functional layer.

In order to avoid the oxidation of the metal layer, an anti-oxidation layer is formed on the surface of the metal layer by vacuum evaporation or magnetron sputtering, the anti-oxidation layer is made of a material of inert metal, such as gold, platinum, nickel, nickel-gold alloy and the like.

S102, the metal layers are processed to form metal mesh 120 on the insulating layer 110 by exposure and development. The metal mesh 120 has a plurality of voids 121 arranged in array.

In the illustrated embodiment, the shapes and sizes of the plurality of voids 121 are the same. The voids 121 are square, diamond, triangular or hexagonal voids arranged in array. The metal mesh 120 includes a plurality of mutually paralleled first metal lines 123 and a plurality of mutually paralleled second metal lines 125.

The widths (D) of the lines (i.e. the first metal lines 123 and the second metal lines 125) of the metal mesh 120 are greater than or equal to 45 nm and less than or equal to 40000 nm. It should be noted that the widths (D) of the first metal lines 123 and the second metal lines 125 of the metal mesh 120 have an impact to the resolution of the touch screen 10, when widths (D) of the lines of the metal mesh 120 are too large, the lines will be seen, thus the resolution of the touch screen 10 may be impacted. Preferably, the widths (D) of the lines of the metal mesh 120 are greater than or equal to 45 nm and less than or equal to 5000 nm.

The relationship of aperture ratio (K) of the metal mesh 120, the transmittance (T₁) of the conductive component 10, and the transmittance (T₂) of the insulating layer is described as the following formula: T₁=T₂*K.

The metal mesh 120 is arranged on the insulating layer 110 in the conductive component 10. In use, a patterned sensing layer on the insulating layer 110 can be achieved by exposing and developing the metal mesh as needed, and then applied to touch screen. Furthermore, the first metal lines 123 and the second metal lines 125 can be processed to mesh wires by exposure and development as needed. The use of indium tin oxide is avoided in the conductive component 10, thus the cost of the conductive component 10 is low. At the same time, the metal mesh 120 is prepared by exposure and development, the process is simple high efficiency.

It should be understood that the descriptions of the examples are specific and detailed, but those descriptions can not be used to limit the present disclosure. Therefore, the scope of protection of the invention patent should be subject to the appended claims.

What is claimed is:

1. A conductive component, comprising:
an insulating layer and a metal mesh arranged on the insulating layer, the insulating layer having a first surface and a second surface opposite to the first surface, the metal mesh comprising two layers, one layer of the metal mesh is arranged on the first surface of the insulating layer, the other layer of the metal meshes is arranged on the second surface of the insulating layer, the metal meshes defining a plurality of voids arranged in array, a relationship of the aperture ratio K of the voids of the metal mesh, the optical transmittance T₁ of the conductive component, and the optical transmittance T₂ of the insulating layer being described as formula: T₁=T₂*K.

2. The conductive component according to claim 1, wherein the voids are square or diamond, the metal mesh comprises a plurality of parallel first metal lines and a plurality of parallel second metal lines, the first metal lines and the second metal lines are intersected with each other to form the voids.

3. The conductive component according to claim 2, wherein at least one of the first metal lines and the second metal lines is solid line or grid line.

4. The conductive component according to claim 2, wherein the widths of the first metal lines and the second metal lines are greater than or equal to 45 nm and less than or equal to 40000 nm.

5. The conductive component according to claim 4, wherein the widths of the first metal lines and the second metal lines are greater than or equal to 45 nm and less than or equal to 5000 nm.

6. The conductive component according to claim 1, wherein the voids of the metal meshes are regular hexagons in a honeycomb arrangement.

7. The conductive component according to claim 1, wherein the voids of the metal mesh are triangular, the metal mesh comprises a plurality of paralleled first metal lines, a plurality of paralleled second metal lines and a plurality of paralleled third metal lines, the first metal lines and the second metal lines are leant to and intersected with each other to form a plurality of diamond voids arranged in array, the third metal lines pass through two opposite ends of the corresponding diamond voids to divide the diamond voids into triangular voids.

8. The conductive component according to claim 7, wherein at least one of the first metal lines, the second metal lines and the third metal lines is solid line or grid line.

9. The conductive component according to claim 7, wherein the widths of the first metal lines, the second metal lines and the third metal lines are greater than or equal to 45 nm and less than or equal to 5000 nm.

10. The conductive component according to claim 9, wherein the widths of the first metal lines, the second metal lines and the third metal lines are greater than or equal to 45 nm and less than or equal to 5000 nm.

11. The conductive component according to claim 1, wherein the metal meshes are provided with an anti-oxidation layer on a surface thereof, the anti-oxidation layer is made of a material selected from the group consisting of gold, platinum, nickel, and nickel-gold alloy.

12. The conductive component according to claim 1, wherein an orthographic projection of the metal mesh arranged on the first surface of the insulating layer to the second surface overlaps the metal mesh arranged on the second surface of the insulating layer.

13. The conductive component according to claim 1, wherein the insulating layer is a glass substrate or a plastic film.

14. The conductive component according to claim 13, wherein the glass substrate is made of a material selected from the group consisting of inorganic silicate glass and polymethyl methacrylate.

15. The conductive component according to claim 13, wherein the plastic film is made of a material selected from the group consisting of polyethylene terephthalate and polycarbonate.

16. The conductive component according to claim 1, wherein the insulating layer is provided with a functional layer having functions of anti-dazzle, hardening, antireflection and atomization on a surface thereof, the metal meshes are formed on the surfaces of the functional layer.

17. The conductive component according to claim 16, wherein the functional layer having the function of antireflection is selected from the group consisting of titanium dioxide coating, magnesium fluoride coating and calcium fluoride coating.

18. The conductive component according to claim 1, wherein the thicknesses of the metal meshes are greater than or equal to 45 nm and less than or equal to 40000 nm.

19. A method of preparing a conductive component, comprising the following steps:
forming two metal layers on a first surface and a second surface opposite to the first surface of an insulating layer, respectively; and
processing the metal layers to form a metal mesh with two layers respectively arranged on the first surface and the second surface of the insulating layer by exposure and development, and the metal mesh defining a plurality of voids arranged in array, a relationship of the aperture ratio K of the voids of the metal mesh, the optical transmittance T₁ of the conductive component, and the optical transmittance T₂ of the insulating layer being described as the formula: T₁=T₂*K.

20. The method of preparing a conductive component according to claim 19, wherein the voids are square or diamond, the metal mesh comprises a plurality of paralleled first metal lines and a plurality of paralleled second metal lines, the first metal lines and the second metal lines are intersected with each other to form the voids.

21. The method of preparing a conductive component according to claim 20, wherein at least one of the first metal lines and the second metal lines is solid line or grid line.

22. The method of preparing a conductive component according to claim 20, wherein the widths of the first metal lines and the second metal lines are greater than or equal to 45 nm and less than or equal to 40000 nm.

23. The method of preparing a conductive component according to claim 22, wherein the widths of the first metal lines and the second metal lines are greater than or equal to 45 nm and less than or equal to 5000 nm.

24. The method of preparing a conductive component according to claim 19, wherein the voids of the metal meshes are regular hexagon in a honeycomb arrangement.

25. The method of preparing a conductive component according to claim 1, wherein the voids of the metal meshes are triangular, the metal mesh comprises a plurality of paralleled first metal lines, a plurality of paralleled second metal lines and a plurality of paralleled third metal lines, the first metal lines and the second metal lines are leant to and intersected to form a plurality of diamond voids arranged in array, the third metal lines pass through the two opposite ends of the corresponding diamond void to divide the diamond voids into triangular voids.

26. The method of preparing a conductive component according to claim 7, wherein at least one of the first metal lines, the second metal lines and the third metal lines is solid line or grid line.

27. The method of preparing a conductive component according to claim 7, wherein the widths of the first metal lines, the second metal lines and the third metal lines are greater than or equal to 45 nm and less than or equal to 40000 nm.

28. The method of preparing a conductive component according to claim 27, wherein the widths of the first metal lines, the second metal lines and the third metal lines are greater than or equal to 45 nm and less than or equal to 5000 nm.

29. The method of preparing a conductive component according to claim 19, wherein the metal meshes are provided with an anti-oxidation layer on a surface thereof, the anti-oxidation layer is made of a material selected from the group consisting of gold, platinum, nickel, and gold-nickel alloy.

30. The method of preparing a conductive component according to claim 19, wherein an orthographic projection of the metal mesh arranged on the first surface of the insulating layer to the second surface overlaps to the metal mesh arranged on the second surface of the insulating layer

31. The method of preparing a conductive component according to claim 19, wherein the insulating layer is a glass substrate or a plastic film.

32. The method of preparing a conductive component according to claim 31, wherein the glass substrate is made of a material selected from the group consisting of inorganic silicate glass and polymethyl methacrylate.

33. The method of preparing a conductive component according to claim 31, wherein the plastic film is made of a material selected from the group consisting of polyethylene terephthalate and polycarbonate.

34. The method of preparing a conductive component according to claim 19, wherein the insulating layer is provided with a functional layer having functions of anti-dazzle, hardening, antireflection and atomization on a surface thereof, the metal mesh is formed on the surface of the functional layer.

35. The method of preparing a conductive component according to claim 34, wherein the functional layer having the function of antireflection is selected from the group consisting of titanium dioxide coating, magnesium fluoride coating and calcium fluoride coating.

36. The method of preparing a conductive component according to claim 19, wherein the thicknesses of the metal meshes are greater than or equal to 45 nm and less than or equal to 40000 nm.
